(19) United States
(12) Patent Application Publication
(10) Pub. No.: US 2019/0363705 A1
(43) Pub. Date: Nov. 28, 2019

(54) SWITCH CIRCUIT AND POWER SOURCE APPARATUS

(71) Applicants: AutoNetworks Technologies, Ltd., Yokkaichi, Mie (JP); Sumitomo Wiring Systems, Ltd., Yokkaichi, Mie (JP); Sumitomo Electric Industries, Ltd., Osaka-Shi (JP)

(72) Inventors: Katsuma Tsukamoto, Yokkaichi, Mie (JP); Kota Oda, Yokkaichi, Mie (JP)

(21) Appl. No.: 16/462,428

(22) PCT Filed: Nov. 14, 2017
(86) PCT No.: PCT/JP2017/040832

§ 371 Date: May 20, 2019

(30) Foreign Application Priority Data
Nov. 21, 2016 (JP) 2016-226085

(51) Int. Cl. H03K 17/08; H03K 17/687

(52) U.S. Cl. CPC H03K 17/08; H03K 2017/0806; H03K 17/687

(57) ABSTRACT

A switch circuit includes an FET. A first driving unit switches the FET on or off by adjusting, in the FET, the voltage of the gate relative to the potential of the source. If the FET is on, a current flows via the source and drain of the FET. If the first driving unit switches the FET from on to off, a second driving unit switches a reflux switch from off to on.

### CROSS-REFERENCE TO RELATED APPLICATIONS

This application is the U.S. national stage of PCT/JP2017/040832 filed on Nov. 14, 2017, which claims priority of Japanese Patent Application No. JP 2016-226085 filed on Nov. 21, 2016, the contents of which are incorporated herein.

### TECHNICAL FIELD

The present disclosure is related to a switch circuit and a power source apparatus.

### BACKGROUND

JP H05-218833 discloses a switch circuit in which an NPN-type bipolar transistor is used as a semiconductor switch and which performs connection and interruption by switching the semiconductor switch on and off. The bipolar transistor is switched on and off by adjusting the voltage of the base relative to the potential of the emitter.

If the voltage of the base relative to the potential of the emitter becomes higher than or equal to a certain voltage, the bipolar transistor switches on and a current can flow between the collector and the emitter of the bipolar transistor. If the voltage of the base relative to the potential of the emitter becomes lower than the certain voltage, the bipolar transistor switches off and no current flows between the collector and the emitter of the bipolar transistor. If the bipolar transistor is on, the higher the voltage of the base relative to the potential of the emitter, the lower the value of resistance between the collector and the emitter.

With the switch circuit described in JP H05-218833, the positive electrode of a battery is connected to the collector of the bipolar transistor, the emitter of the bipolar transistor is connected to one end of a load, and the negative electrode of the battery and the other end of the load are grounded. If the bipolar transistor is switched on, the battery and the load are connected to one another. When the bipolar transistor is switched off, the connection between the battery and the load is interrupted.

If the bipolar transistor is to be switched on, the voltage of the base relative to the potential of the emitter is increased by increasing the voltage of the base of the bipolar transistor relative to the ground potential. If the bipolar transistor is to be switched off, the voltage of the base relative to the potential of the emitter is decreased by decreasing the voltage of the base of the bipolar transistor relative to the ground potential.

An electric wire connecting the bipolar transistor and the load is an inductive member having an inductance component. Due to this, while the bipolar transistor is on, a current flows through the electric wire and energy is accumulated in the electric wire.

If the voltage of the base of the bipolar transistor relative to the ground potential is decreased in order to switch the bipolar transistor off, the value of resistance between the collector and the emitter of the bipolar transistor increases and the current flowing through the inductive member decreases. In this situation, the inductive member decreases the voltage of the emitter relative to the ground potential in order to maintain the current flowing through the inductive member, and keeps the voltage of the base relative to the potential of the emitter higher than or equal to the certain voltage. Due to this, a current flows via the bipolar transistor and the energy accumulated in the inductive member is discharged. If this energy equals zero, the voltage of the base relative to the potential of the emitter becomes lower than the certain voltage and the bipolar transistor switches off.

While the inductive member is keeping the voltage of the emitter relative to the ground potential higher than or equal to the certain voltage, the value of resistance between the collector and the emitter of the bipolar transistor is high. Due to this, a large amount of power is consumed by the bipolar transistor and a large amount of heat is generated by the bipolar transistor. Accordingly, there is a risk that the bipolar transistor may become hot and a functional deterioration of the bipolar transistor may occur.

In view of this, one aim is to provide a switch circuit in which the amount of heat generated by a semiconductor switch if the semiconductor switch is switched off is small, and a power source apparatus including the switch circuit.

### Effects of Present Disclosure

### SUMMARY

According to the present disclosure, the amount of heat generated by a semiconductor switch if the semiconductor switch is switched off is small.

A switch circuit pertaining to one aspect of the present disclosure is a switch circuit including a semiconductor switch through which a current flows via a first terminal and a second terminal and which switches on or off in accordance with a voltage of a control terminal relative to a potential of the first terminal, the switch circuit including: a voltage regulator that keeps a voltage between the first terminal and the second terminal of the semiconductor switch lower than or equal to a predetermined voltage; a switch that has one end connected to the first terminal of the semiconductor switch; a first switching unit that switches the semiconductor switch from on to off and a second switching unit that switches the switch from off to on if the first switching unit switches the semiconductor switch from on to off.

A switch circuit pertaining to one aspect of the present disclosure is a switch circuit including a semiconductor switch through which a current flows via a first terminal and a second terminal and which switches on or off in accordance with a voltage of a control terminal relative to a potential of the first terminal, the switch circuit including: a voltage regulator that keeps a voltage between the first terminal and the second terminal of the semiconductor switch lower than or equal to a predetermined voltage; and a diode having a cathode connected to the first terminal of the semiconductor switch.

A power source apparatus pertaining to one aspect of the present disclosure includes: a switch circuit described above; and two capacitors that are connected to one another via the switch circuit.

### BRIEF DESCRIPTION OF DRAWINGS

FIG. 1 is a block diagram illustrating a structure of a main part of a power source apparatus in Embodiment 1.

FIG. 2 is an explanatory diagram showing an operation of a switch circuit in which a reflux switch and a Zener diode are not provided.

FIG. 3 is an explanatory diagram showing an operation of a switch circuit.

FIG. 4 is another explanatory diagram showing the operation of the switch circuit.

FIG. 5 is a block diagram illustrating a structure of a main part of a power source apparatus in Embodiment 2.

FIG. 6 is a block diagram illustrating a structure of a main part of a power source apparatus in Embodiment 3.

FIG. 7 is a block diagram illustrating a structure of a main part of a power source apparatus in Embodiment 4.

FIG. 8 is a block diagram illustrating a structure of a main part of a power source apparatus in Embodiment 5.

FIG. 9 is a block diagram illustrating a structure of a main part of a power source apparatus in Embodiment 6.

FIG. 10 is a block diagram illustrating a structure of a main part of a power source apparatus in Embodiment 7.

### DESCRIPTION OF EMBODIMENTS OF PRESENT DISCLOSURE

First, aspects of implementation of the present disclosure are listed and described. At least some of the embodiments described in the following may be combined as desired.

A switch circuit pertaining to one aspect of the present disclosure is a switch circuit including a semiconductor switch through which a current flows via a first terminal and a second terminal and which switches on or off in accordance with a voltage of a control terminal relative to a potential of the first terminal, the switch circuit including: a voltage regulator that keeps a voltage between the first terminal and the second terminal of the semiconductor switch lower than or equal to a predetermined voltage; a switch that has one end connected to the first terminal of the semiconductor switch; a first switching unit that switches the semiconductor switch from on to off and a second switching unit that switches the switch from off to on if the first switching unit switches the semiconductor switch from on to off.

In the one aspect described above, a current flows through the second terminal and the first terminal of the semiconductor switch in that order, for example, if the semiconductor switch is on and the switch is off. An electric wire having one end connected to the first terminal of the semiconductor switch is an inductive member having an inductance component. Due to this, if a current is flowing through the semiconductor switch, energy is accumulated in the electric wire.

If the semiconductor switch is switched off, the switch is switched on. In this case, when the other end of the switch is connected to the other end of the electric wire, a current flows from the electric wire via the switch, and the energy accumulated in the electric wire is discharged. Due to this, after the semiconductor switch switches from on to off, the voltage at the first terminal of the semiconductor switch relative to a fixed potential, e.g., the ground potential, hardly decreases and the semiconductor switch is kept off. Consequently, the amount of heat generated by the semiconductor switch if the semiconductor switch switches off is small.

While a current is flowing through the second terminal and the first terminal of the semiconductor switch, energy is also accumulated in an electric wire having one end connected to the second terminal of the semiconductor switch. If the semiconductor switch is switched off, this electric wire increases the voltage at the second terminal of the semiconductor switch. Due to this, the voltage between the first terminal and the second terminal of the semiconductor switch increases, but this voltage is kept lower than or equal to the predetermined voltage by the voltage regulator. Due to this, no large voltage is applied to the semiconductor switch.

The switch circuit pertaining to one aspect of the present disclosure further includes a voltage detection unit that detects a voltage at the first terminal of the semiconductor switch, and the second switching unit switches the switch off if the voltage detected by the voltage detection unit becomes higher than or equal to a voltage threshold value after the second switching unit switches the switch on.

In the one aspect described above, for example, the voltage at the first terminal of the semiconductor switch relative to a fixed potential is detected. The switch is switched off if the voltage at the first terminal of the semiconductor switch becomes higher than or equal to the voltage threshold value after the switch is switched on. Due to this, it becomes possible to switch the switch off after all the energy accumulated in the electric wire connected to the first terminal of the semiconductor switch is discharged.

The switch circuit pertaining to one aspect of the present disclosure further includes a second semiconductor switch through which a current flows via a third terminal and a fourth terminal and which switches on or off in accordance with a voltage of a second control terminal relative to a potential of the third terminal, and the first terminal of the semiconductor switch is connected to the third terminal of the second semiconductor switch or the second terminal of the semiconductor switch is connected to the fourth terminal of the second semiconductor switch, and the first switching unit simultaneously switches the semiconductor switch and the second semiconductor switch from on to off.

In the one aspect described above, the semiconductor switch and the second semiconductor switch are connected to one another and are simultaneously switched from on to off. If each of the semiconductor switch and the second semiconductor switch is an N-channel type field effect transistor (FET), the source of the semiconductor switch, which functions as the first terminal, is connected to the source of the second semiconductor switch, which functions as the third terminal, or the drain of the semiconductor switch, which functions as the second terminal, is connected to the drain of the second semiconductor switch, which functions as the fourth terminal. In this case, when the semiconductor switch and the second semiconductor switch are off, no current flows via parasitic diodes of the semiconductor switch and the second semiconductor switch.

A switch circuit pertaining to one aspect of the present disclosure is a switch circuit including a semiconductor switch through which a current flows via a first terminal and a second terminal and which switches on or off in accordance with a voltage of a control terminal relative to a potential of the first terminal, the switch circuit including: a voltage regulator that keeps a voltage between the first terminal and the second terminal of the semiconductor switch lower than or equal to a predetermined voltage; and a diode having a cathode connected to the first terminal of the semiconductor switch.

In the one aspect described above, a current flows through the second terminal and the first terminal of the semiconductor switch, for example, if the semiconductor switch is on. An electric wire having one end connected to the first terminal of the semiconductor switch is an inductive member having an inductance component. Due to this, if a current is flowing through the semiconductor switch, energy is accumulated in the electric wire.

If the semiconductor switch is switched off, the electric wire decreases the voltage at the first terminal of the semiconductor switch. Furthermore, if the voltage of the cathode relative to the potential of the anode becomes higher than or equal to a forward voltage in the diode, a current flows from the electric wire via the diode and the energy accumulated in the electric wire is discharged. The forward voltage is a voltage difference occurring between both ends of the diode if a forward current flows through the diode. For example, if the potential of the anode of the diode is the fixed potential, the voltage at the first terminal of the semiconductor switch relative to the fixed potential hardly fluctuates and the semiconductor switch is kept off after the semiconductor switch switches from on to off because the energy accumulated in the electric wire is discharged as described above. Consequently, the amount of heat generated by the semiconductor switch if the semiconductor switch switches off is small.

While a current is flowing through the second terminal and the first terminal of the semiconductor switch, energy is also accumulated in an electric wire having one end connected to the second terminal of the semiconductor switch. If the semiconductor switch switches off, this electric wire increases the voltage at the second terminal of the semiconductor switch. Due to this, the voltage between the first terminal and the second terminal of the semiconductor switch increases, but this voltage is kept lower than or equal to the predetermined voltage by the voltage regulator. Due to this, no large voltage is applied to the semiconductor switch.

The switch circuit pertaining to one aspect of the present disclosure further includes: a second semiconductor switch through which a current flows via a third terminal and a fourth terminal and which switches on or off in accordance with a voltage of a second control terminal relative to a potential of the third terminal; and a switching unit that simultaneously switches the semiconductor switch and the second semiconductor switch from on to off, and the first terminal of the semiconductor switch is connected to the third terminal of the second semiconductor switch or the second terminal of the semiconductor switch is connected to the fourth terminal of the second semiconductor switch.

In the one aspect described above, the semiconductor switch and the second semiconductor switch are connected to one another and are simultaneously switched from on to off. If each of the semiconductor switch and the second semiconductor switch is an N-channel type FET, the source of the semiconductor switch, which functions as the first terminal, is connected to the source of the second semiconductor switch, which functions as the third terminal, or the drain of the semiconductor switch, which functions as the second terminal, is connected to the drain of the second semiconductor switch, which functions as the fourth terminal. In this case, when the semiconductor switch and the second semiconductor switch are off, no current flows via parasitic diodes of the semiconductor switch and the second semiconductor switch.

In the switch circuit pertaining to one aspect of the present disclosure, no current flows through the voltage regulator if a voltage applied to the voltage regulator is lower than the predetermined voltage and a current flows through the voltage regulator if the voltage applied to the voltage regulator equals the predetermined voltage.

In the one aspect described above, the voltage regulator is a Zener diode, a varistor, or the like. If the voltage applied to the voltage regulator becomes equal to the predetermined voltage, a current flows via the voltage regulator, and the voltage applied to the voltage regulator is kept lower than or equal to the predetermined voltage.

A power source apparatus pertaining to one aspect of the present disclosure includes: a switch circuit described above; and two capacitors that are connected to one another via the switch circuit.

In the one aspect described above, one capacitor supplies power to the other capacitor via the switch circuit and charges the other capacitor.

### DETAILS OF EMBODIMENTS OF THE DISCLOSURE

In the following, specific examples of switch circuits and power source apparatuses pertaining to embodiments of the present disclosure are described with reference to the drawings. Note that the present disclosure is not limited to these examples, and the present disclosure is intended to include all modifications that are indicated by the claims and are within the meaning and scope of equivalents of the claims.

### Embodiment 1

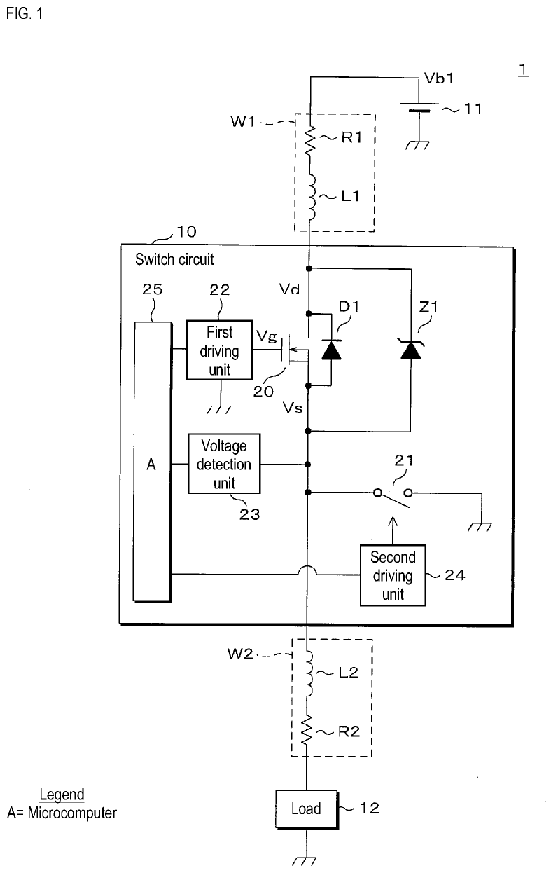

FIG. 1 is a block diagram illustrating a structure of a main part of a power source apparatus 1 in Embodiment 1. The power source apparatus 1 is suitably mounted in a vehicle, and includes a switch circuit 10, a battery 11, a load 12, and electric wires W1 and W2. Each of the electric wires W1 and W2 is an inductive member having a resistance component and an inductance component. An equivalent circuit of the electric wire W1 can be expressed as a series circuit of a resistor R1 and an inductor L1. An equivalent circuit of the electric wire W2 can be expressed as a series circuit of a resistor R2 and an inductor L2.

The positive electrode of the battery 11 is connected to one end of the electric wire W1. The other end of the electric wire W1 is connected to the switch circuit 10. One end of the electric wire W2 is also connected to the switch circuit 10. The other end of the electric wire W2 is connected to one end of the load 12. The negative electrode of the battery 11 and the other end of the load 12 are grounded.

The switch circuit 10 connects the electric wires W1 and W2 to each other and interrupts their connection. While the switch circuit 10 is connecting the electric wires W1 and W2, the battery 11 supplies power to the load 12 via the electric wire W1, the switch circuit 10, and the electric wire W2. The load 12 is an electric device mounted in the vehicle and operates using power supplied from the battery 11. While the switch circuit 10 is interrupting the connection between the electric wires W1 and W2, no power is supplied from the battery 11 to the load 12 and the load 12 does not operate.

The switch circuit 10 includes an N-channel type FET 20, a reflux switch 21, a first driving unit 22, a voltage detection unit 23, a second driving unit 24, a microcomputer 25, a diode D1, and a Zener diode Z1. The diode D1 is a parasitic diode of the FET 20. The cathode and anode of the diode D1 are respectively connected to the drain and the source of the FET 20.

The drain of the FET 20 is connected to the other end of the electric wire W1 and its source is connected to the one end of the electric wire W2. The cathode and anode of the Zener diode Z1 are respectively connected to the drain and the source of the FET 20. One end of the reflux switch 21 and the voltage detection unit 23 are connected to the source of the FET 20. The other end of the reflux switch 21 is grounded. The gate of the FET 20 is connected to the first driving unit 22. The first driving unit 22, the voltage detection unit 23, and the second driving unit 24 are each separately connected to the microcomputer 25. The first driving unit 22 is grounded.

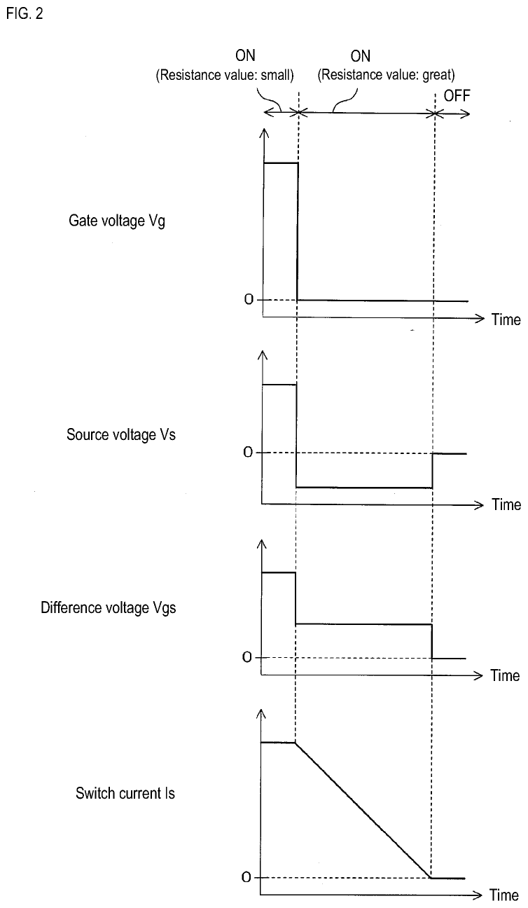

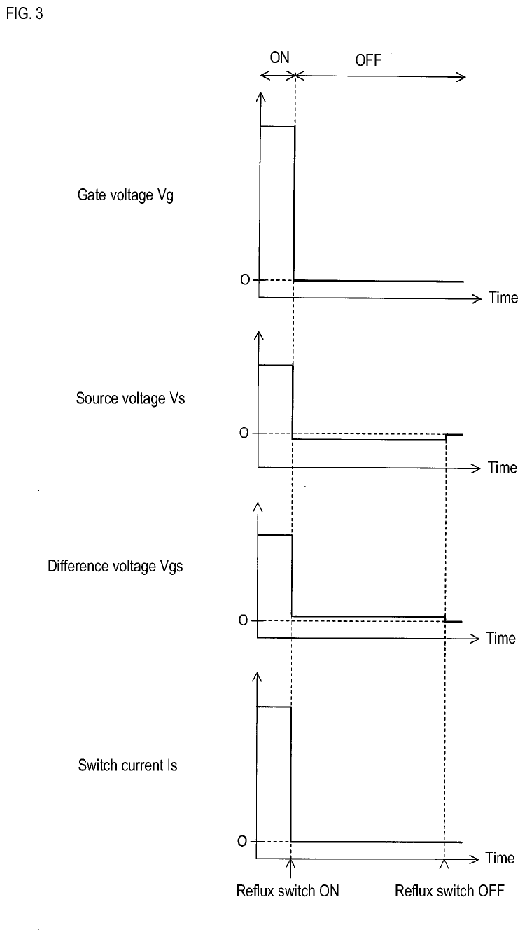

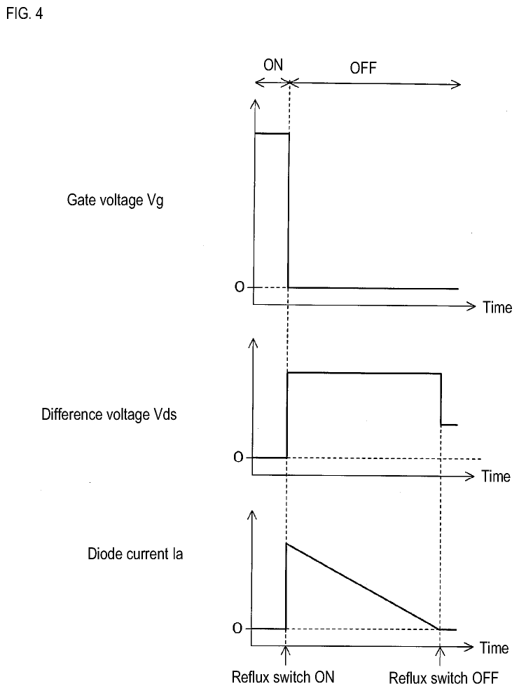

In the following, the voltages of the drain, source, and gate of the FET 20 relative to the ground potential are referred to as a drain voltage Vd, source voltage Vs, and gate voltage Vg. Furthermore, in the FET 20, the voltage of the gate relative to the potential of the source is referred to as a difference voltage Vgs (refer to FIGS. 2 and 3). In the FET 20, the voltage of the drain relative to the potential of the source is referred to as a difference voltage Vds (refer to FIG. 4).

The FET 20 functions as a semiconductor switch. In the FET 20, a current flows via the drain and source if the difference voltage Vgs is higher than or equal to a certain positive voltage. The FET 20 is on in this situation. In the FET 20, no current flows via the drain and source if the difference voltage Vgs is lower than the certain positive voltage. The FET 20 is off in this situation. In Embodiment 1, the source, drain, and gate of the FET 20 respectively function as a first terminal, second terminal, and control terminal.

The first driving unit 22 receives, from the microcomputer 25, input of a first instruction signal providing an instruction to switch the FET 20 on or off. If the instruction provided by the first instruction signal changes from off to on, the first driving unit 22 increases the difference voltage Vgs by increasing the gate voltage Vg and switches the FET 20 from off to on. Due to this, the electric wires W1 and W2 are connected to one another.

If the instruction provided by the first instruction signal changes from on to off, the first driving unit 22 decreases the difference voltage Vgs by decreasing the gate voltage Vg and switches the FET 20 from on to off. Due to this, the connection between the electric wires W1 and W2 is interrupted.

The first driving unit 22 functions as a first switching unit.

The Zener diode Z1 functions as a voltage regulator and keeps the difference voltage Vds lower than or equal to a certain reference voltage. This reference voltage is a so-called breakdown voltage. If the difference voltage Vds is lower than the reference voltage, no voltage flows through the Zener diode Z1. If the difference voltage Vds is equal to the reference voltage, a current flows from the cathode to the anode through the Zener diode Z1. The reference voltage is set to a voltage higher than the maximum value of the voltage across both terminals of the battery 11 (referred to in the following as a battery voltage Vb1).

The voltage detection unit 23 detects the source voltage Vs, and outputs voltage information indicating the detected source voltage Vs to the microcomputer 25.

The second driving unit 24 receives, from the microcomputer 25, input of a second instruction signal providing an instruction to switch the reflux switch 21 on or off. If the instruction provided by the second instruction signal changes from off to on, the second driving unit 24 switches the reflux switch 21 from off to on. If the instruction provided by the second instruction signal changes from on to off, the second driving unit 24 switches the reflux switch 21 from on to off. The reflux switch 21 is a FET, a bipolar transistor, a relay contact, or the like.

The microcomputer 25 changes the instruction provided through each of the first instruction signal and the second instruction signal. For example, the microcomputer 25 changes the instruction provided by the first instruction signal from off to on if a connection signal that is an instruction to connect the electric wires W1 and W2 to one another is input to the microcomputer 25. In this situation, the first driving unit 22 switches the FET 20 from off to on. Consequently, power is supplied from the battery 11 to the load 12 via the electric wire W1, the FET 20, and the electric wire W2. While power is being supplied from the battery 11 to the load 12, energy is accumulated in the respective inductors L1 and L2 of the electric wires W1 and W2.

If an interruption signal that is an instruction to interrupt the connection between the electric wires W1 and W2 is input to the microcomputer 25, then the microcomputer 25 changes the instruction provided by the first instruction signal from on to off and changes the instruction provided by the second instruction signal from off to on. Due to this, the first driving unit 22 switches the FET 20 from on to off and the second driving unit 24 switches the reflux switch 21 from off to on. As a result, the connection between the electric wires W1 and W2 is interrupted, and power supply from the battery 11 to the load 12 stops. Furthermore, due to the actions of the reflux switch 21 and the Zener diode Z1, the energy accumulated in the inductors L1 and L2 of the electric wires W1 and W2 is appropriately discharged.

The second driving unit 24 functions as a second switching unit that switches the reflux switch 21 on if the first driving unit 22 switches the FET 20 from on to off.

The microcomputer 25 changes the instruction provided by the second instruction signal from on to off if the source voltage Vs detected by the voltage detection unit 23 becomes higher than or equal to a voltage threshold value after changing the instruction provided by the second instruction signal from off to on. The voltage threshold value is fixed and is set in advance. In the example illustrated in FIG. 1, the voltage threshold value is 0V. Accordingly, the second driving unit 24 switches the reflux switch 21 from on to off if the source voltage Vs detected by the voltage detection unit 23 becomes higher than or equal to the fixed voltage threshold value after the second driving unit 24 switches the reflux switch 21 from off to on.

FIG. 2 is an explanatory diagram showing an operation of a switch circuit in which the reflux switch 21 and the Zener diode Z1 are not provided. This switch circuit is a circuit yielded by removing the reflux switch 21 and the Zener diode Z1 from the switch circuit 10. FIG. 2 shows the changes of the gate voltage Vg, the source voltage Vs, and the difference voltage Vgs. FIG. 2 also shows the change of a switch current Is flowing through the FET 20. The switch current Is is an absolute value.

If the instruction provided by the first instruction signal is on, the first driving unit 22 adjusts the gate voltage Vg to a setting voltage set in advance. When the gate voltage Vg is adjusted to the setting voltage, the difference voltage Vgs is higher than or equal to the certain positive voltage and the FET 20 is on. In this situation, the value of the resistance between the drain and the source of the FET 20 is low because the difference voltage Vgs is sufficiently high. If the gate voltage Vg is adjusted to the setting voltage, the source voltage Vs substantially equals the battery voltage Vb1 because the voltage drop occurring between the drain and the source of the FET 20 is small. Accordingly, the setting voltage is sufficiently higher than the battery voltage Vb1.

If the gate voltage Vg is adjusted to the setting voltage, a current flows from the battery 11 to the load 12 via the electric wire W1, the FET 20, and the electric wire W2, and energy is accumulated in the inductors L1 and L2 of the electric wires W1 and W2. In this situation, the switch current Is is large.

If the instruction provided by the first instruction signal changes from on to off, the first driving unit 22 decreases the gate voltage Vg to 0V. Due to this, the current flowing through the electric wires W1 and W2 decreases because the value of the resistance between the drain and the source of the FET 20 increases. In this situation, the inductor L1 of the electric wire W1 increases the drain voltage Vd in order to maintain the magnitude of the current flowing through the electric wire W1. Furthermore, the inductor L2 of the electric wire W2 decreases the source voltage Vs in order to maintain the magnitude of the current flowing through the electric wire W2.

The inductor L2 of the electric wire W2 decreases the source voltage Vs until the difference voltage Vgs becomes higher than or equal to the certain positive voltage. Due to this, the FET 20 is kept on even after the gate voltage Vg is adjusted to 0V. While the FET 20 is on, a current flows through the electric wire W1, the FET 20, and the electric wire W2 in that order, and the energy accumulated in the inductors L1 and L2 of the electric wires W1 and W2 is discharged. While the inductors L1 and L2 are discharging energy, the source voltage Vs and the difference voltage Vgs remain fixed and the switch current Is decreases at a constant gradient.

If all energy accumulated in the inductors L1 and L2 of the electric wires W1 and W2 is discharged, or that is, if the switch current Is becomes 0 A, the source voltage Vs increases to 0V and the difference voltage Vgs decreases to 0V. Due to this, the FET 20 switches off. Naturally, the switch current Is is 0 A if the FET 20 is off.

While the inductors L1 and L2 of the electric wires W1 and W2 are discharging energy, the value of the resistance between the drain and the source of the FET 20 is great because the difference voltage Vgs is low. Due to this, a large amount of power is consumed by the FET 20 and a large amount of heat is generated by the FET 20. Accordingly, there is a risk that the FET 20 may become hot and a functional deterioration of the FET 20 may occur.

FIG. 3 is an explanatory diagram showing an operation of the switch circuit 10. FIG. 3 shows the changes of the gate voltage Vg, the source voltage Vs, the difference voltage Vgs, and the switch current Is, similarly to FIG. 2.

If the instruction provided by the first instruction signal is on, the first driving unit 22 adjusts the gate voltage Vg to the setting voltage. When the gate voltage Vg is adjusted to the setting voltage, the difference voltage Vgs is higher than or equal to the certain positive voltage and the FET 20 is on. In this situation, the value of the resistance between the drain and the source of the FET 20 is low because the difference voltage Vgs is sufficiently high. If the gate voltage Vg is adjusted to the setting voltage, the source voltage Vs substantially equals the battery voltage Vb1 because the voltage drop occurring between the drain and the source of the FET 20 is small. Accordingly, the setting voltage is sufficiently higher than the battery voltage Vb1.

If the gate voltage Vg is adjusted to the setting voltage, a current flows from the battery 11 to the load 12 via the electric wire W1, the FET 20, and the electric wire W2, and energy is accumulated in the inductors L1 and L2 of the electric wires W1 and W2. In this situation, the switch current Is is large.

As described above, if switching the FET 20 from on to off, the microcomputer 25 changes the instruction provided by the first instruction signal from on to off and changes the instruction provided by the second instruction signal from off to on. Due to this, the first driving unit 22 decreases the gate voltage Vg to 0V and the second driving unit 24 switches the reflux switch 21 from off to on.

As described above, if the gate voltage Vg decreases to 0V, the inductor L1 of the electric wire W1 increases the drain voltage Vd and the inductor L2 of the electric wire W2 decreases the source voltage Vs. Here, because the reflux switch 21 is on, a current flows through the load 12 and the reflux switch 21 from the electric wire W2, and the inductor L2 of the electric wire W2 discharges energy. The inductor L2 of the electric wire W2 decreases the source voltage Vs only by an amount making it possible for the inductor L2 to discharge energy via the reflux switch 21. Due to this, the source voltage Vs hardly decreases from 0V.

Because the source voltage Vs hardly decreases from 0V, the difference voltage Vgs is lower than the certain positive voltage while the inductor L2 of the electric wire W2 is discharging energy. Accordingly, if the gate voltage Vg decreases to 0V, the FET 20 switches from on to off, and the FET 20 is kept off thereafter. Accordingly, the amount of heat generated by the FET 20 if the FET 20 switches off is small.

While the inductor L2 of the electric wire W2 is discharging energy, the source voltage Vs and the difference voltage Vgs remain fixed and the current flowing through the reflux switch 21 decreases at a constant gradient. If all energy accumulated in the inductor L2 of the electric wire W2 is discharged, or that is, if the current flowing through the reflux switch 21 becomes 0 A, the source voltage Vs increases to 0V and the difference voltage Vgs decreases to 0V. Due to this, the FET 20 does not switch on and is kept off.

While the gate voltage Vg is adjusted to 0V, the switch current Is is kept at 0 A because the FET 20 is kept off. If the voltage detected by the voltage detection unit 23, or that is, the source voltage Vs becomes higher than or equal to 0V, the microcomputer 25 changes the instruction provided by the second instruction signal from on to off and the second driving unit 24 switches the reflux switch 21 from on to off. Accordingly, the reflux switch 21 switches from on to off after all energy accumulated in the inductor L2 of the electric wire W2 is discharged.

FIG. 4 is another explanatory diagram showing the operation of the switch circuit 10. FIG. 4 shows the changes of the gate voltage Vg and the difference voltage Vds. FIG. 4 further shows the change of a diode current Ia flowing through the Zener diode Z1. The diode current Ia is an absolute value. The change of the gate voltage Vg shown in FIG. 3 and FIG. 4 is the same.

If the gate voltage Vg is adjusted to 0V, the source voltage Vs is substantially 0V because the energy accumulated in the inductor L2 of the electric wire W2 is discharged through the reflux switch 21. However, the difference voltage Vds increases to the reference voltage of the Zener diode Z1 because the inductor L1 of the electric wire W1 increases the drain voltage Vd. If the difference voltage Vds reaches the reference voltage, a current flows from the electric wire W1 via the Zener diode Z1 and the energy accumulated in the inductor L1 of the electric wire W1 is discharged. The difference voltage Vds is kept lower than or equal to the reference voltage. Due to this, no large voltage is applied between the drain and the source of the FET 20.

While the inductor L1 of the electric wire W1 is discharging energy, the drain voltage Vd and the difference voltage Vds remain fixed. If the gate voltage Vg is adjusted to the setting voltage, the diode current Ia is 0 A because the difference voltage Vds is substantially 0V. The diode current Ia increases if the gate voltage Vg is adjusted from the setting voltage to 0V. While the inductor L1 of the electric wire W1 is discharging energy, the diode current Ia decreases at a constant gradient.

If all energy accumulated in the inductor L1 of the electric wire W1 is discharged, or that is, if the diode current Ia becomes 0 A, the difference voltage Vds decreases from the reference voltage to the battery voltage Vb1. While the difference voltage Vds is lower than the reference voltage, the diode current Ia is 0 A. The timing at which the second driving unit 24 switches the reflux switch 21 from on to off substantially coincides with the timing at which the diode current Ia becomes 0 A.

### Embodiment 2

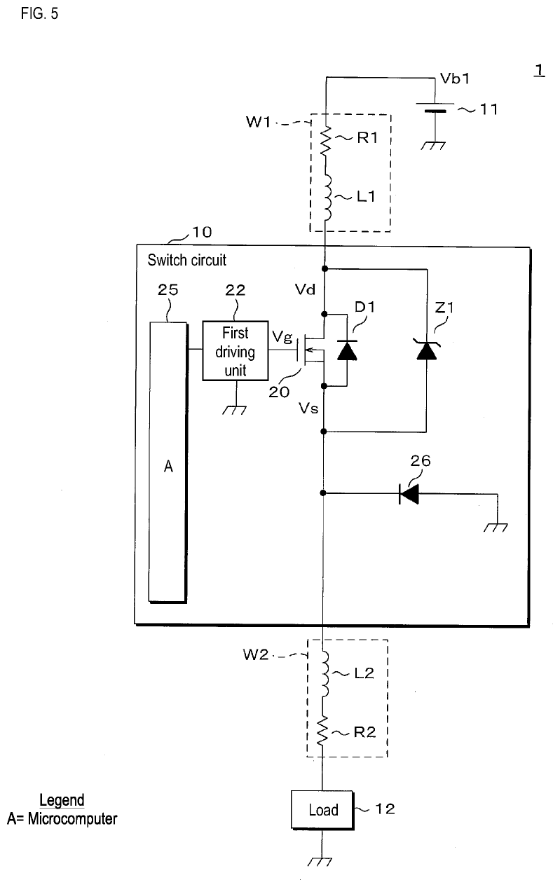

FIG. 5 is a block diagram illustrating a structure of a main part of a power source apparatus 1 in Embodiment 2.

In the following, points differing from Embodiment 1 are described with regard to Embodiment 2. Structures other than the structures described in the following are common between Embodiment 1 and Embodiment 2, and thus, the components common with Embodiment 1 are provided with the same reference symbols as those in Embodiment 1 and description thereof is omitted.

In the power source apparatus 1 in Embodiment 2, the structure of the switch circuit 10 differs compared to that in the power source apparatus 1 in Embodiment 1. With regard to the components included in the switch circuit 10 in Embodiment 1, the switch circuit 10 in Embodiment 2 includes a free-wheeling diode 26 in place of the reflux switch 21, the voltage detection unit 23, and the second driving unit 24. The cathode of the free-wheeling diode 26 is connected to the source of the FET 20 and the anode of the free-wheeling diode 26 is grounded. Accordingly, if the FET 20 is on, no current flows through the free-wheeling diode 26 because the source voltage Vs is a positive voltage.

In the switch circuit 10 in Embodiment 2, the gate voltage Vg, the source voltage Vs, the difference voltage Vgs, the switch current Is, the difference voltage Vds, and the diode current Ia change similarly to Embodiment 1, with the exception of the following differences. Differences between Embodiments 1 and 2 relating to these changes are described.

If the gate voltage Vg decreases to 0V, the drain voltage Vd increases and the source voltage Vs decreases, similarly to Embodiment 1. If the voltage of the anode relative to the potential of the cathode becomes higher than or equal to a forward voltage in the free-wheeling diode 26, a current flows through the load 12 and the free-wheeling diode 26 from the electric wire W2, and the inductor L2 of the electric wire W2 discharges energy. The forward voltage is the voltage drop occurring at the free-wheeling diode 26 if a current flows through the free-wheeling diode 26. The inductor L2 of the electric wire W2 decreases the source voltage Vs only by an amount making it possible for the inductor L2 to discharge energy via the free-wheeling diode 26. Accordingly, the source voltage Vs is kept at a negative voltage having an absolute value equal to the forward voltage. Due to this, the source voltage Vs hardly decreases from 0V.

Because the source voltage Vs hardly decreases from 0V, the difference voltage Vgs is lower than the certain positive voltage while the inductor L2 of the electric wire W2 is discharging energy. Accordingly, if the gate voltage Vg decreases to 0V, the FET 20 switches from on to off, and the FET 20 is kept off thereafter. Accordingly, the amount of heat generated by the FET 20 if the FET 20 switches off is small.

While the inductor L2 of the electric wire W2 is discharging energy, the source voltage Vs and the difference voltage Vgs remain fixed and the current flowing through the free-wheeling diode 26 decreases at a constant gradient. If all energy accumulated in the inductor L2 of the electric wire W2 is discharged, or that is, if the current flowing through the free-wheeling diode 26 becomes 0 A, the source voltage Vs increases to 0V and the difference voltage Vgs decreases to 0V. Due to this, the FET 20 does not switch on and is kept off. While the gate voltage Vg is adjusted to 0V, the switch current Is is kept at 0 A because the FET 20 is kept off.

The power source apparatus 1 and the switch circuit 10 in Embodiment 2 have effects similar to those in Embodiment 1.

### Embodiment 3

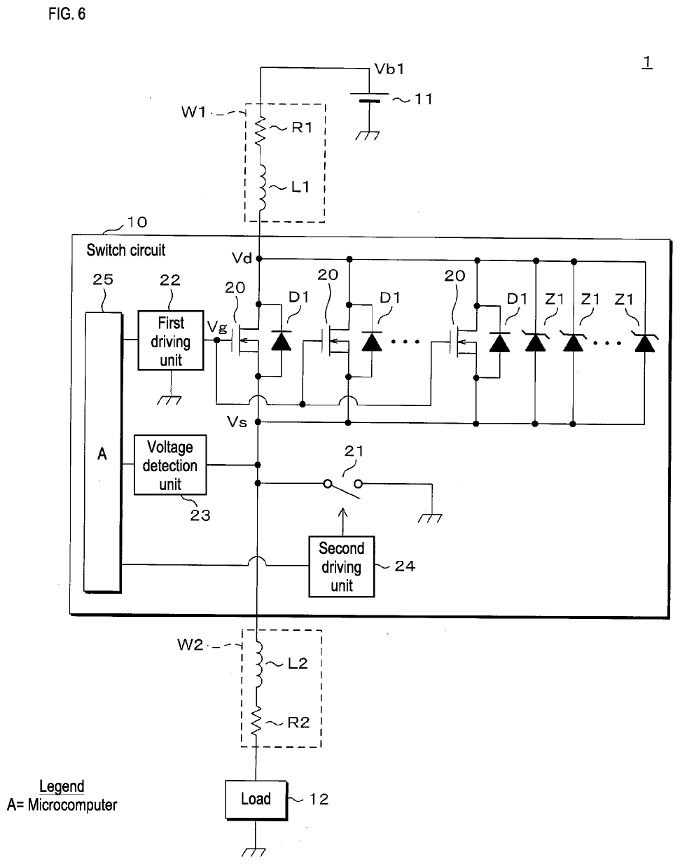

FIG. 6 is a block diagram illustrating a structure of a main part of a power source apparatus 1 in Embodiment 3.

In the following, points differing from Embodiment 1 are described with regard to Embodiment 3. Structures other than the structures described in the following are common between Embodiment 1 and Embodiment 3, and thus, the components common with Embodiment 1 are provided with the same reference symbols as those in Embodiment 1 and description thereof is omitted.

In the power source apparatus 1 in Embodiment 3, the structure of the switch circuit 10 differs compared to that in the power source apparatus 1 in Embodiment 1. The switch circuit 10 in Embodiment 3 has two or more of each of the FET 20, the diode D1, and the Zener diode Z1.

A diode D1 is connected to each of the plurality of FETs 20, 20, . . . , similarly to Embodiment 1. Accordingly, the number of diodes D1 equals the number of FETs 20. Each of the plurality of FETs 20, 20, . . . is connected similarly to Embodiment 1. Accordingly, the drain and the source of each FET 20 are respectively connected to the drain and the source of another FET 20. The gate of each of the plurality of FETs 20, 20, . . . is connected to the same one end of the first driving unit 22. Each of the plurality of Zener diodes Z1, Z1, . . . is connected similarly to Embodiment 1. Accordingly, the cathode and the anode of each Zener diode Z1 are respectively connected to the cathode and the anode of another Zener diode Z1.

The first driving unit 22 simultaneously switches the plurality of FETs 20, 20, . . . on or off. Here, the term “simultaneously” not only means that the switching timings to on or off completely coincide but also means that the switching timings to on or off substantially coincide. Furthermore, the reference voltages of the Zener diodes Z1, Z1, . . . are substantially equal.

The power source apparatus 1 and the switch circuit 10 in Embodiment 3 have effects similar to those in Embodiment 1.

Note that in Embodiment 3, the number of FETs 20 may be one and the number of Zener diodes Z1 may be two or more. Furthermore, the number of Zener diodes Z1 may be one and the number of FETs 20 may be two or more. Furthermore, the switch circuit 10 in Embodiment 3 may have a structure in which the free-wheeling diode 26 is included in place of the reflux switch 21, the voltage detection unit 23, and the second driving unit 24, similarly to Embodiment 2.

### Embodiment 4

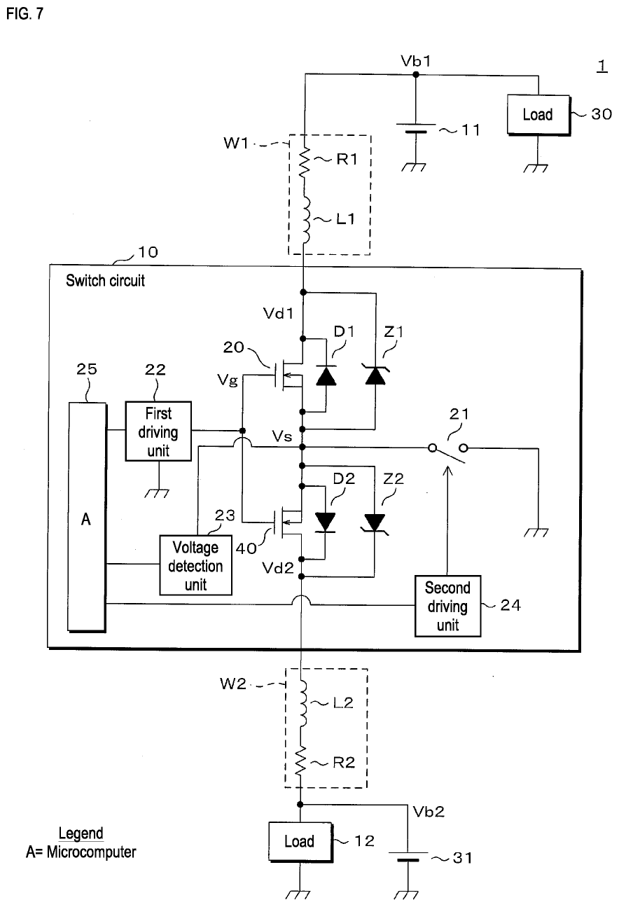

FIG. 7 is a block diagram illustrating a structure of a main part of a power source apparatus 1 in Embodiment 4.

In the following, points differing from Embodiment 1 are described with regard to Embodiment 4. Structures other than the structures described in the following are common between Embodiment 1 and Embodiment 4, and thus, the components common with Embodiment 1 are provided with the same reference symbols as those in Embodiment 1 and description thereof is omitted.

The power source apparatus 1 in Embodiment 4 includes a load 30 and a battery 31 in addition to the switch circuit 10, the battery 11, the load 12, and the electric wires W1 and W2. One end of the load 30 is connected to the positive electrode of the battery 11, and the positive electrode of the battery 31 is connected to a connection node between the load 12 and the electric wire W2. The other end of the load 30 and the negative electrode of the battery 31 are grounded. The batteries 11 and 31 are connected to one another via the switch circuit 10.

While the switch circuit 10 is connecting the electric wires W1 and W2, the battery 11 supplies power to the loads 12 and 30 and the battery 31 when the battery voltage Vb1 is higher than the voltage across both terminals of the battery 31 (referred to in the following as a battery voltage Vb2). Due to this, the battery 31 is charged. In a similar case, the battery 31 supplies power to the loads 12 and 30 and the battery 11 if the battery voltage Vb2 is higher than the battery voltage Vb1. Due to this, the battery 11 is charged. The batteries 11 and 31 each function as an electric energy storage.

If the switch circuit 10 is interrupting the connection between the electric wires W1 and W2, the battery 11 supplies power to the load 30 and the battery 31 supplies power to the load 12.

The load 30 is also an electric device mounted in the vehicle. The loads 12 and 30 each operate using power supplied from one of the batteries 11 and 31.

The switch circuit 10 in Embodiment 4 includes an N-channel type FET 40, a diode D2, and a Zener diode Z2 in addition to the components of the switch circuit 10 in Embodiment 1. The diode D2 is a parasitic diode of the FET 40. The cathode and anode of the diode D2 are respectively connected to the drain and the source of the FET 40.

The source of the FET 40 is connected to the source of the FET 20 and the its drain is connected to the one end of the electric wire W2. The gate of each of the FETs 20 and 40 is connected to the same one end of the first driving unit 22. The cathode and anode of the Zener diode Z2 are respectively connected to the drain and the source of the FET 40. The one end of the reflux switch 21 is connected to the source of each of the FETs 20 and 40. The other end of the reflux switch 21 is grounded. The voltage detection unit 23 is connected to the sources of the FETs 20 and 40 and the microcomputer 25.

The source of the FET 20 is connected to the one end of the electric wire W2 via the FET 40 and the diode D2 or Zener diode Z2. The source of the FET 40 is connected to the other end of the electric wire W1 via the FET 20 and the diode D1 or Zener diode Z1.

In the following, the voltages of the drains of the FETs 20 and 40 relative to the ground potential are respectively referred to as drain voltages Vd1 and Vd2. Furthermore, the voltage at the drain of the FET 20, relative to the potential of its source is referred to as a difference voltage Vds1. The voltage at the drain of the FET 40 relative to the potential of its source is referred to as a difference voltage Vds2. The gate voltages of the FETs 20 and 40 relative to the ground potential are the same, their source voltages relative to the ground potential are also the same, and their gate voltages relative to the potential of the source are also the same.

The FET 40 also functions as a semiconductor switch. In the FET 40, a current flows via the drain and source if the difference voltage Vgs is higher than or equal to a certain positive voltage. The FET 40 is on in this situation. In the FET 40, no current flows via the drain and source if the difference voltage Vgs is lower than the certain positive voltage. The FET 40 is off in this situation. The certain voltages pertaining to the FETs 20 and 40 are substantially equal.

One of the sources of the FETs 20 and 40 functions as a first terminal and the other one of the sources functions as a third terminal. One of the drains of the FETs 20 and 40 functions as a second terminal and the other one of the drains functions as a fourth terminal. One of the gates of the FETs 20 and 40 functions as a control terminal and the other one of the gates functions as a second control terminal.

The Zener diode Z1 functions similarly to Embodiment 1. Accordingly, the Zener diode Z1 keeps the difference voltage Vds1 lower than or equal to the reference voltage. The Zener diode Z2 also functions as a voltage regulator, similarly to the Zener diode Z1, and keeps the difference voltage Vds2 lower than or equal to a certain second reference voltage. This second reference voltage is also a so-called breakdown voltage. If the difference voltage Vds2 is lower than the second reference voltage, no voltage flows through the Zener diode Z2. If the difference voltage Vds2 is equal to the second reference voltage, a current flows from the cathode to the anode through the Zener diode Z2. Each of the reference voltage and the second reference voltage is set to a voltage higher than the maximum value of the difference between the battery voltages Vb1 and Vb2.

Furthermore, the Zener diodes Z1 and Z2 function similarly to ordinary diodes if currents flow therethrough in a forward direction. Accordingly, a current flows in the forward direction in each of the Zener diodes Z1 and Z2 if the voltage of the anode relative to the potential of the cathode is higher than or equal to a certain voltage.

The first instruction signal provides an instruction to switch the FETs 20 and 40 on or off. If the instruction provided by the first instruction signal changes from off to on, the first driving unit 22 increases the difference voltage Vgs by increasing the gate voltage Vg and simultaneously switches the FETs 20 and 40 from off to on. Due to this, the electric wires W1 and W2 are connected to one another. If the instruction provided by the first instruction signal changes from on to off, the first driving unit 22 decreases the difference voltage Vgs by decreasing the gate voltage Vg and simultaneously switches the FETs 20 and 40 from on to off. Due to this, the connection between the electric wires W1 and W2 is interrupted. Here, the term “simultaneously” has the same meaning as in Embodiment 3.

No current flows via the diodes D1 and D2 if the FETs 20 and 40 are off because the sources of the FETs 20 and 40 are connected to one another as described above.

In Embodiment 4, the source voltage Vs, the difference voltage Vgs, and the switch current Is each change similarly to Embodiment 1 in accordance with the gate voltage Vg. Here, the switch current Is is the absolute value of the current flowing via the FETs 20 and 40.

If the gate voltage Vg is equal to the setting voltage, the FETs 20 and 40 are on because the difference voltage Vgs is higher than or equal to the certain voltages. If the FETs 20 and 40 are on, a current flows through the electric wires W1 and W2 and energy is accumulated in the inductors L1 and L2 of the electric wires W1 and W2.

If a current is flowing through the electric wire W1, the FETs 20 and 40, and the electric wire W2 in that order, the drain voltage Vd1 increases and the drain voltage Vd2 decreases when the gate voltage Vg is adjusted to 0V from the setting voltage. The source voltage Vs decreases as the drain voltage Vd2 decreases.

When the gate voltage Vg is adjusted to 0V, a current flows from the electric wire W2 to the reflux switch 21 via the load 12 or the battery 31 and the energy accumulated in the inductor L2 of the electric wire W2 is discharged because the reflux switch 21 is on. Due to this, the source voltage Vs hardly decreases, similarly to Embodiment 1, and the difference voltage Vgs is lower than the certain voltages while the inductor L2 of the electric wire W2 is discharging energy. Consequently, the FETs 20 and 40 are kept off after the gate voltage Vg is adjusted to 0V.

If a current is flowing through the electric wire W1, the FETs 20 and 40, and the electric wire W2 in that order, the difference voltage Vds1 and the diode current Ia flowing through the Zener diode Z1 change similarly to Embodiment 1. Accordingly, if the gate voltage Vg is adjusted to 0V from the setting voltage, the difference voltage Vds1 increases to the reference voltage when the drain voltage Vd1 increases. If the difference voltage Vds1 reaches the reference voltage, a current flows from the electric wire W1 via the Zener diode Z1 and the energy accumulated in the inductor L1 of the electric wire W1 is discharged. The difference voltage Vds1 is kept lower than or equal to the reference voltage.

If a current is flowing through the electric wire W2, the FETs 40 and 20, and the electric wire W1 in that order, the drain voltage Vd2 increases and the drain voltage Vd1 decreases when the gate voltage Vg is adjusted to 0V from the setting voltage. The source voltage Vs decreases as the drain voltage Vd1 decreases.

If the gate voltage Vg is adjusted to 0V, a current flows from the electric wire W1 to the reflux switch 21 via the battery 11 or the load 30 and the energy accumulated in the inductor L1 of the electric wire W1 is discharged because the reflux switch 21 is on. Due to this, the source voltage Vs hardly decreases similarly to Embodiment 1 while the inductor L1 of the electric wire W1 is discharging energy. Consequently, the FETs 20 and 40 are kept off after the gate voltage Vg is adjusted to 0V.

If a current is flowing through the electric wire W2, the FETs 40 and 20, and the electric wire W1 in that order, the difference voltage Vds2 and the diode current Ib flowing through the Zener diode Z2 change similarly to Embodiment 1. Accordingly, if the gate voltage Vg is adjusted to 0V from the setting voltage, the difference voltage Vds2 increases to the second reference voltage when the drain voltage Vd2 increases. If the difference voltage Vds2 reaches the second reference voltage, a current flows from the electric wire W2 via the Zener diode Z2 and the energy accumulated in the inductor L2 of the electric wire W2 is discharged. The difference voltage Vds2 is kept lower than or equal to the second reference voltage.

The power source apparatus 1 and the switch circuit 10 in Embodiment 4 have effects similar to those in Embodiment 1.

### Embodiment 5

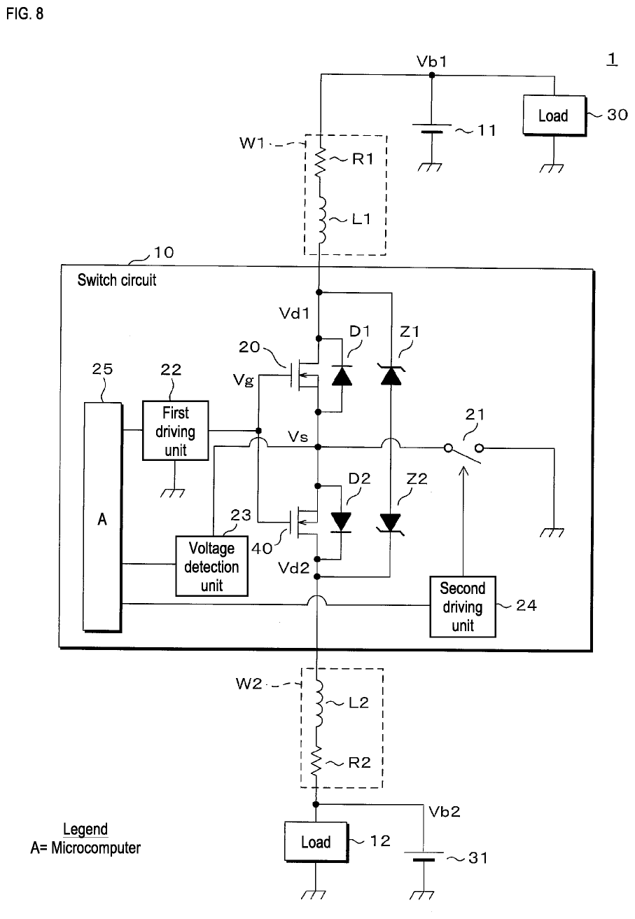

FIG. 8 is a block diagram illustrating a structure of a main part of a power source apparatus 1 in Embodiment 5.

In the following, points differing from Embodiment 4 are described with regard to Embodiment 5. Structures other than the structures described in the following are common between Embodiment 4 and Embodiment 5, and thus, the components common with Embodiment 4 are provided with the same reference symbols as those in Embodiment 4 and description thereof is omitted.

In the power source apparatus 1 in Embodiment 5, the structure of the switch circuit 10 differs compared to that in the power source apparatus 1 in Embodiment 4. In the switch circuit 10 in Embodiment 5, the anodes of the Zener diodes Z1 and Z2 are connected to one another. The anodes of the Zener diodes Z1 and Z2 are not respectively connected to the sources of the FETs 20 and 40.

In the following, an absolute value of the voltage between the drains of the FETs 20 and 40 is referred to as a difference voltage Vdd.

In the switch circuit 10 in Embodiment 5, if a current is flowing through the electric wire W1, the FETs 20 and 40, and the electric wire W2 in that order, the drain voltage Vd1 increases and the difference voltage Vdd increases to a certain third reference voltage when the gate voltage Vg is adjusted to 0V from the setting voltage. If the difference voltage Vdd reaches the third reference voltage, a current flows through the Zener diodes Z1 and Z2 and the difference voltage Vdd is kept lower than or equal to the third reference voltage. The difference voltage Vds1 is lower than the difference voltage Vdd. Due to this, the difference voltage Vds1 is also kept lower than or equal to the third reference voltage. The series circuit constituted of the Zener diodes Z1 and Z2 also functions as a voltage regulator.

Similarly, if a current is flowing through the electric wire W2, the FETs 40 and 20, and the electric wire W1 in that order, the drain voltage Vd2 increases and the difference voltage Vdd increases to the third reference voltage when the gate voltage Vg is adjusted to 0V from the setting voltage. If the difference voltage Vdd reaches the third reference voltage, a current flows through the Zener diodes Z1 and Z2 and the difference voltage Vdd is kept lower than or equal to the third reference voltage. The difference voltage Vds2 is lower than the difference voltage Vdd. Due to this, the difference voltage Vds2 is also kept lower than or equal to the third reference voltage.

The power source apparatus 1 and the switch circuit 10 in Embodiment 5 have effects similar to those in Embodiment 4.

Note that in Embodiment 5, also the cathodes of the Zener diodes Z1 and Z2 may be connected to one another. In this case, the anodes of the Zener diodes Z1 and Z2 are respectively connected to the drains of the FETs 20 and 40. Furthermore, the number of series circuits constituted of Zener diodes Z1 and Z2 the anodes of which are connected to one another or the cathodes of which are connected to one another may also be two or more. In this case, the plurality of series circuits are connected in parallel.

Furthermore, the switch circuits 10 in Embodiments 4 and 5 may have a structure in which the free-wheeling diode 26 is included in place of the reflux switch 21, the voltage detection unit 23, and the second driving unit 24, similarly to Embodiment 2. In this case, the cathode of the free-wheeling diode 26 is connected to the sources of the FETs 20 and 40 and the anode thereof is grounded. If the source voltage Vs becomes a negative voltage having an absolute value equal to the forward voltage of the free-wheeling diode 26, a current flows from the electric wire W1 or W2 through the free-wheeling diode 26 and the electric wire W1 or W2 discharges energy.

### Embodiment 6

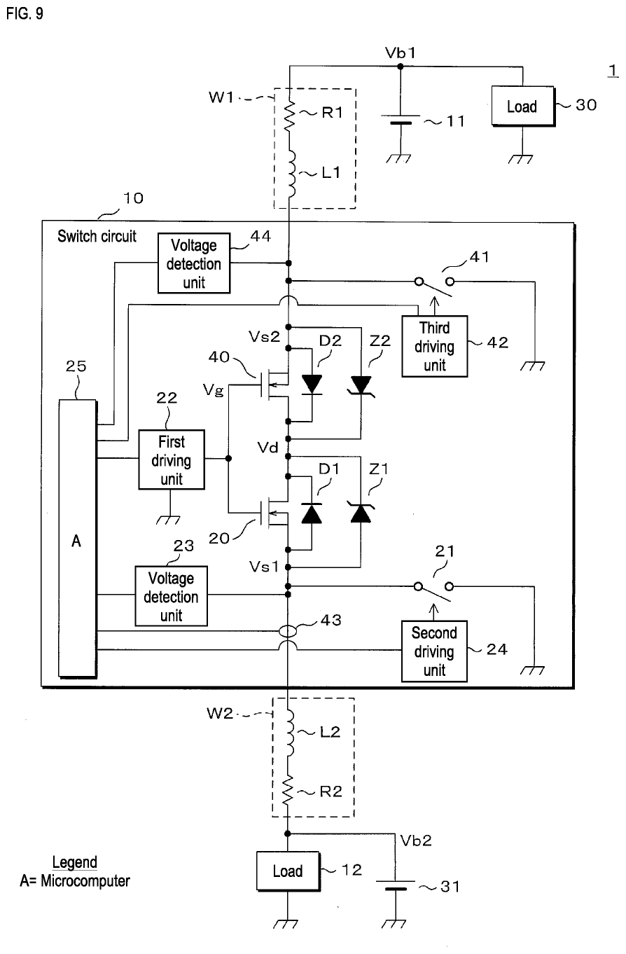

FIG. 9 is a block diagram illustrating a structure of a main part of a power source apparatus 1 in Embodiment 6.

In the following, points differing from Embodiment 4 are described with regard to Embodiment 6. Structures other than the structures described in the following are common between Embodiment 4 and Embodiment 6, and thus, the components common with Embodiment 4 are provided with the same reference symbols as those in Embodiment 4 and description thereof is omitted.

In the power source apparatus 1 in Embodiment 6, the structure of the switch circuit 10 differs compared to that in the power source apparatus 1 in Embodiment 4. The switch circuit 10 in Embodiment 6 includes a reflux switch 41, a third driving unit 42, a current sensor 43, and a voltage detection unit 44 in addition to the components included in the switch circuit 10 in Embodiment 4.

The source of the FET 40 is connected to the other end of the electric wire W1. The drain of the FET 40 is connected to the drain of the FET 20. The source of the FET 20 is connected to the one end of the electric wire W2. Similarly to Embodiment 4, the cathode and the anode of the Zener diode Z1 are respectively connected to the drain and the source of the FET 20, and the cathode and the anode of the Zener diode Z2 are respectively connected to the drain and the source of the FET 40.

One end of the reflux switch 41 is further connected to the source of the FET 40. The other end of the reflux switch 41 is grounded. The third driving unit 42 and the current sensor 43 are each separately connected to the microcomputer 25. The voltage detection unit 44 is separately connected to each of the source of the FET 40 and the microcomputer 25. The one end of the reflux switch 21 is connected to the source of the FET 20, and the other end of the reflux switch 21 is grounded. The voltage detection unit 23 is separately connected to each of the source of the FET 20 and the microcomputer 25.

No current flows via the diodes D1 and D2 if the FETs 20 and 40 are off because the drains of the FETs 20 and 40 are connected to one another.

In the following, the voltages of the sources of the FETs 20 and 40 relative to the ground potential are respectively referred to as source voltages Vs1 and Vs2. The voltages of the drains of the FETs 20 and 40 relative to the ground potential are the same. The voltage of the drain of the FET 20 relative to the ground potential is referred to as a drain voltage Vd. The voltages at the gate and drain of the FET 20 relative to the potential of its source are respectively referred to as difference voltages Vgs1 and Vds1. The voltages at the gate and drain of the FET 40 relative to the potential of its source are respectively referred to as difference voltages Vgs2 and Vds2. The voltage at the source of the FET 40 relative to the potential of the source of the FET 20 is referred to as a difference voltage Vss.

The voltage detection unit 23 detects the source voltage Vs1, and outputs voltage information indicating the detected source voltage Vs1 to the microcomputer 25. Similarly, the voltage detection unit 44 detects the source voltage Vs2, and outputs voltage information indicating the detected source voltage Vs2 to the microcomputer 25.

The third driving unit 42 receives, from the microcomputer 25, input of a third instruction signal providing an instruction to switch the reflux switch 41 on or off. If the instruction provided by the third instruction signal changes from off to on, the third driving unit 42 switches the reflux switch 41 from off to on. If the instruction provided by the third instruction signal changes from on to off, the third driving unit 42 switches the reflux switch 41 from on to off. The microcomputer 25 changes the instruction provided by the third instruction signal. The reflux switch 41 is a FET, a bipolar transistor, a relay contact, or the like.

In Embodiment 5, the second driving unit 24 and the third driving unit 42 each function as a second switching unit.

The current sensor 43 detects a current flowing through the drains of the FETs 20 and 40. The current sensor 43 detects a positive current if a current is flowing from the source of the FET 20 to the source of the FET 40 and detects a negative current if a current is flowing from the source of the FET 40 to the source of the FET 20. The current sensor 43 outputs current information indicating the detected current to the microcomputer 25. If the FETs 20 and 40 are on, the microcomputer 25 determines whether a current is flowing through the electric wire W1, the FETs 40 and 20, and the electric wire W2 in that order or a current is flowing through the electric wire W2, the FETs 20 and 40, and the electric wire W1 in that order, based on whether or not the current indicated by the current information input from the current sensor 43 has a positive voltage.

Note that the current sensor 43 may detect a negative current if a current is flowing from the source of the FET 20 to the source of the FET 40 and detect a positive current if a current is flowing from the source of the FET 40 to the source of the FET 20.

For example, the microcomputer 25 changes the instruction provided by the first instruction signal from off to on if the connection signal described in Embodiment 1 is input to the microcomputer 25. Due to this, the first driving unit 22 switches the FETs 20 and 40 on.

If a current is flowing through the electric wire W1, the FETs 40 and 20, and the electric wire W2 in that order, the microcomputer 25, for example, changes the instruction provided by the first instruction signal from on to off and changes the instruction provided by the second instruction signal from off to on when the interruption signal described in Embodiment 1 is input to the microcomputer 25. The microcomputer 25 changes the instruction provided by the second instruction signal from on to off if the source voltage Vs1 detected by the voltage detection unit 23 becomes higher than or equal to the voltage threshold value after changing the second instruction signal to on. Accordingly, the first driving unit 22 switches the FETs 20 and 40 off and the second driving unit 24 switches the reflux switch 21 from off to on. The second driving unit 24 switches the reflux switch 21 from on to off if the source voltage Vs1 detected by the voltage detection unit 23 becomes higher than or equal to the voltage threshold value after the reflux switch 21 switches on.

If a current is flowing through the electric wire W2, the FETs 20 and 40, and the electric wire W1 in that order, the microcomputer 25, for example, changes the instruction provided by the first instruction signal from on to off and changes the instruction provided by the third instruction signal from off to on when the interruption signal described in Embodiment 1 is input to the microcomputer 25. The microcomputer 25 changes the instruction provided by the third instruction signal from on to off if the source voltage Vs2 detected by the voltage detection unit 44 becomes higher than or equal to a second voltage threshold value after changing the third instruction signal to on. Accordingly, the first driving unit 22 switches the FETs 20 and 40 off and the third driving unit 42 switches the reflux switch 41 from off to on. The third driving unit 42 switches the reflux switch 41 from on to off if the source voltage Vs2 detected by the voltage detection unit 44 becomes higher than or equal to the second voltage threshold value after the reflux switch 41 switches on. The second voltage threshold value is fixed and is set in advance. In the example illustrated in FIG. 9, each of the voltage threshold value and the second voltage threshold value is 0V.

If a current is flowing through the electric wire W1, the FETs 40 and 20, and the electric wire W2 in that order, the source voltage Vs1 decreases when the gate voltage Vg is adjusted to 0V from the setting voltage. In this situation, the reflux switch 21 is on. Due to this, a current flows from the electric wire W2 to the reflux switch 21 via the load 12 or the battery 31 and the energy accumulated in the inductor L2 of the electric wire W2 while the FETs 20 and 40 are on is discharged. Due to this, the source voltage Vs1 hardly decreases and the difference voltage Vgs1 is lower than the certain positive voltage while the inductor L2 of the electric wire W2 is discharging energy. Consequently, the FET 20 is kept off after the gate voltage Vg is adjusted to 0V. The reflux switch 21 switches off if all energy accumulated in the inductor L2 of the electric wire W2 is discharged and the source voltage Vs1 detected by the voltage detection unit 23 becomes higher than or equal to the voltage threshold value.

If a current is flowing through the electric wire W1, the FETs 40 and 20, and the electric wire W2 in that order, the source voltage Vs2 increases from the battery voltage Vb1 when the gate voltage Vg is adjusted to 0V from the setting voltage. Due to this, the difference voltage Vgs2 is lower than or equal to 0V and is lower than the certain positive voltage. Consequently, the FET 40 is also kept off after the gate voltage Vg is adjusted to 0V.

If a current is flowing through the electric wire W1, the FETs 40 and 20, and the electric wire W2 in that order, the drain voltage Vd also increases when the gate voltage Vg is adjusted to 0V from the setting voltage because the source voltage Vs2 increases as described above. Due to this, the difference voltage Vds1 increases to the reference voltage. If the difference voltage Vds1 reaches the reference voltage, a current flows from the electric wire W1 through the Zener diode Z1 and the energy accumulated in the inductor L1 of the electric wire W1 is discharged. The difference voltage Vds1 is kept lower than or equal to the reference voltage.

If a current is flowing through the electric wire W2, the FETs 20 and 40, and the electric wire W1 in that order, the source voltage Vs2 decreases when the gate voltage Vg is adjusted to 0V from the setting voltage. In this situation, the reflux switch 41 is on. Due to this, a current flows from the electric wire W1 to the reflux switch 41 via the battery 11 or the load 30 and the energy accumulated in the inductor L2 of the electric wire W2 while the FETs 20 and 40 are on is discharged. Due to this, the source voltage Vs2 hardly decreases and the difference voltage Vgs2 is lower than the certain positive voltage while the inductor L1 of the electric wire W1 is discharging energy. Consequently, the FET 40 is kept off after the gate voltage Vg is adjusted to 0V. The reflux switch 41 switches off if all energy accumulated in the inductor L1 of the electric wire W1 is discharged and the source voltage Vs2 detected by the voltage detection unit 44 becomes higher than or equal to the second voltage threshold value.

If a current is flowing through the electric wire W2, the FETs 20 and 40, and the electric wire W1 in that order, the source voltage Vs1 increases from the battery voltage Vb2 when the gate voltage Vg is adjusted to 0V from the setting voltage. Due to this, the difference voltage Vgs1 is lower than or equal to 0V and is lower than the certain positive voltage. Consequently, the FET 20 is also kept off after the gate voltage Vg is adjusted to 0V.

If a current is flowing through the electric wire W2, the FETs 20 and 40, and the electric wire W1 in that order, the drain voltage Vd also increases when the gate voltage Vg is adjusted to 0V from the setting voltage because the source voltage Vs1 increases as described above. Due to this, the difference voltage Vds2 increases to the second reference voltage. If the difference voltage Vds2 reaches the second reference voltage, a current flows from the electric wire W2 through the Zener diode Z2 and the energy accumulated in the inductor L2 of the electric wire W2 is discharged. The difference voltage Vds1 is kept lower than or equal to the second reference voltage.

The power source apparatus 1 and the switch circuit 10 in Embodiment 6 have effects similar to those in Embodiment 4.

### Embodiment 7

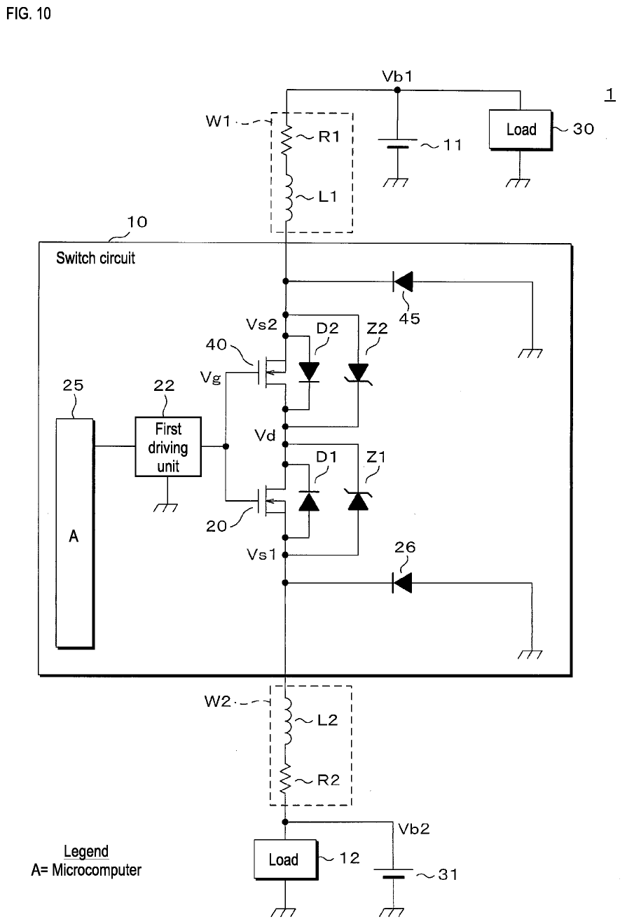

FIG. 10 is a block diagram illustrating a structure of a main part of a power source apparatus 1 in Embodiment 7.

In the following, points differing from Embodiment 6 are described with regard to Embodiment 7. Structures other than the structures described in the following are common between Embodiment 6 and Embodiment 7, and thus, the components common with Embodiment 6 are provided with the same reference symbols as those in Embodiment 6 and description thereof is omitted.

In the power source apparatus 1 in Embodiment 7, the structure of the switch circuit 10 differs compared to that in the power source apparatus 1 in Embodiment 6. With regard to the components included in the switch circuit 10 in Embodiment 6, the switch circuit 10 in Embodiment 7 includes the free-wheeling diode 26 described in Embodiment 2 in place of the reflux switch 21, the voltage detection unit 23, and the second driving unit 24 and includes a free-wheeling diode 45 in place of the reflux switch 41, the third driving unit 42, and the voltage detection unit 44. In the switch circuit 10 in Embodiment 7, the current sensor 43 need not be provided.

The cathode of the free-wheeling diode 26 is connected to the source of the FET 20 and the anode thereof is grounded. The cathode of the free-wheeling diode 45 is connected to the source of the FET 40 and its anode is grounded. Accordingly, if the FETs 20 and 40 are on, no current flows through the free-wheeling diodes 26 and 45 because the source voltages Vs1 and Vs2 are positive voltages.

The switch circuit 10 in Embodiment 7 functions similarly to Embodiment 6 with the exception of the following differences. Differences between Embodiments 6 and 7 regarding the function of the switch circuit 10 are described.

Similarly to Embodiment 6, the microcomputer 25 changes the first instruction signal between on or off and the first driving unit 22 switches the FETs 20 and 40 on or off according to the instruction provided by the first instruction signal. The first driving unit 22 also functions as a switching unit.

If a current is flowing through the electric wire W1, the FETs 40 and 20, and the electric wire W2 in that order, the source voltage Vs1 decreases when the gate voltage Vg is adjusted to 0V from the setting voltage. If the source voltage Vs1 becomes a negative voltage having an absolute value equal to the forward voltage of the free-wheeling diode 26, a current flows from the electric wire W2 to the free-wheeling diode 26 via the load 12 or the battery 31, and the energy accumulated in the inductor L2 of the electric wire W2 while the FETs 20 and 40 are on is discharged. Due to this, the source voltage Vs1 hardly decreases and the difference voltage Vgs1 is lower than the certain positive voltage while the inductor L2 of the electric wire W2 is discharging energy. Consequently, the FET 20 is kept off after the gate voltage Vg is adjusted to 0V.

If a current is flowing through the electric wire W1, the FETs 40 and 20, and the electric wire W2 in that order, the source voltage Vs2 increases from the battery voltage Vb1 when the gate voltage Vg is adjusted to 0V from the setting voltage. Due to this, the difference voltage Vgs2 is lower than or equal to 0V and is lower than the certain positive voltage. Consequently, the FET 40 is also kept off after the gate voltage Vg is adjusted to 0V. Furthermore, no current flows through the free-wheeling diode 45.

If a current is flowing through the electric wire W2, the FETs 20 and 40, and the electric wire W1 in that order, the source voltage Vs2 decreases when the gate voltage Vg is adjusted to 0V from the setting voltage. If the source voltage Vs2 becomes a negative voltage having an absolute value equal to a forward voltage of the free-wheeling diode 45, a current flows from the electric wire W1 to the free-wheeling diode 45 via the battery 11 or the load 30, and the energy accumulated in the inductor L1 of the electric wire W1 while the FETs 20 and 40 are on is discharged. Due to this, the source voltage Vs2 hardly decreases and the difference voltage Vgs2 is lower than the certain positive voltage while the inductor L1 of the electric wire W1 is discharging energy. Consequently, the FET 40 is kept off after the gate voltage Vg is adjusted to 0V.

The forward voltage of the free-wheeling diode 45 is defined similarly to the forward voltage of the free-wheeling diode 26.

If a current is flowing through the electric wire W2, the FETs 20 and 40, and the electric wire W1 in that order, the source voltage Vs1 increases from the battery voltage Vb2 when the gate voltage Vg is adjusted to 0V from the setting voltage. Due to this, the difference voltage Vgs1 is lower than or equal to 0V and is lower than the certain positive voltage. Consequently, the FET 20 is also kept off after the gate voltage Vg is adjusted to 0V. Furthermore, no current flows through the free-wheeling diode 26.

The power source apparatus 1 and the switch circuit 10 in Embodiment 7 have effects similar to those in Embodiment 6.

Note that the number of Zener diodes Z1 may be two or more in Embodiments 4, 6, and 7. In this case, the plurality of Zener diodes Z1, Z1, . . . are connected in parallel similarly to Embodiment 3, and the cathode and the anode of each Zener diode Z1 are respectively connected to the cathode and anode of another Zener diode Z1.

Similarly, the number of Zener diodes Z2 may be two or more in Embodiments 4, 6, and 7. In this case, the plurality of Zener diodes Z2, Z2, . . . are connected in parallel similarly to the plurality of Zener diodes Z1, Z1, . . . in Embodiment 3, and the cathode and the anode of each Zener diode Z2 are respectively connected to the cathode and anode of another Zener diode Z2.

Furthermore, the number of FETs 20 may be two or more in Embodiments 4 to 7. In this case, the plurality of FETs 20, 20, . . . are connected in parallel similarly to Embodiment 3, and the drain and the source of each FET 20 are respectively connected to the drain and the source of another FET 20. The gate of each FET 20 is connected to the same one end of the first driving unit 22. The first driving unit 22 simultaneously switches the plurality of FETs 20, 20, . . . on or off.

Similarly, the number of FETs 40 may be two or more in Embodiments 4 to 7. In this case, the plurality of FETs 40, 40, . . . are connected in parallel similarly to the plurality of FETs 20, 20, . . . in Embodiment 3, and the drain and the source of each FET 40 are respectively connected to the drain and the source of another FET 40. The gate of each FET 40 is connected to the same one end of the first driving unit 22. The first driving unit 22 simultaneously switches the plurality of FETs 40, 40, . . . on or off.

Here, the term “simultaneously” has the same meaning as in Embodiment 3.

Furthermore, in Embodiments 1 to 7, it suffices that the Zener diode Z1 functions as a voltage regulator that keeps the voltage between the drain and the source of the FET 20 lower than or equal to the reference voltage. Due to this, a varistor, for example, may be used in place of the Zener diode Z1.

Similarly, in Embodiments 4 to 7, it suffices that the Zener diode Z2 functions as a voltage regulator that keeps the voltage between the drain and the source of the FET 40 lower than or equal to the second reference voltage. Due to this, a varistor, for example, may be used in place of the Zener diode Z2.

If an absolute value of a voltage across both ends of a varistor is lower than a predetermined voltage, no current flows via the varistor. If an absolute value of the voltage across both ends of a varistor equals the predetermined voltage, a current flows via the varistor. If a voltage regulator such as a varistor is to be used in a case in which the Zener diodes Z1 and Z2 constitute a series circuit as in Embodiment 5, one voltage regulator may be used in place of this series circuit.

Note that in Embodiments 1 and 3 to 6, the switching of the reflux switch 21 to off need not be performed on the basis of the voltage at the source of the FET 20 relative to the ground potential, and for example, may be performed based on a current flowing through the reflux switch 21. In this case, the reflux switch 21 is switched from on to off if the current flowing through the reflux switch 21 equals 0 A.

Similarly, in Embodiment 6, the switching of the reflux switch 41 to off need not be performed on the basis of the voltage at the source of the FET 40 relative to the ground potential, and for example, may be performed based on a current flowing through the reflux switch 41. In this case, the reflux switch 41 is switched from on to off if the current flowing through the reflux switch 41 equals 0 A.

Furthermore, in Embodiments 1 to 3, it suffices that the FET 20 functions as a semiconductor switch. Due to this, a semiconductor switch such as an insulated-gate bipolar transistor (IGBT) or an NPN-type bipolar transistor may be used in place of the FET 20.

Embodiments 1 to 7 disclosed herein are examples in every way and should be construed as being non-limiting. The scope of the present disclosure is indicated not by the meanings described above but by the claims, and the present disclosure is intended to include all modifications within the meaning and scope of equivalents of the claims.

1. A switch circuit including a semiconductor switch through which a current flows via a first terminal and a second terminal and which switches on or off in accordance with a voltage of a control terminal relative to a potential of the first terminal, the switch circuit comprising:
a voltage regulator that keeps a voltage between the first terminal and the second terminal of the semiconductor switch lower than or equal to a predetermined voltage;
a switch that has one end connected to the first terminal of the semiconductor switch;
a first switching unit that switches the semiconductor switch from on to off; and
a second switching unit that switches the switch from off to on if the first switching unit switches the semiconductor switch from on to off.

2. The switch circuit according to claim 1, further comprising a voltage detection unit that detects a voltage of the first terminal of the semiconductor switch, wherein
the second switching unit switches the switch off if the voltage detected by the voltage detection unit becomes higher than or equal to a voltage threshold value after the second switching unit switches the switch on.

3. The switch circuit according to claim 1, further comprising a second semiconductor switch through which a current flows via a third terminal and a fourth terminal and which switches on or off in accordance with a voltage of a second control terminal relative to a potential of the third terminal, wherein
the first terminal of the semiconductor switch is connected to the third terminal of the second semiconductor switch or the second terminal of the semiconductor switch is connected to the fourth terminal of the second semiconductor switch, and
the first switching unit simultaneously switches the semiconductor switch and the second semiconductor switch from on to off.

4. A switch circuit including a semiconductor switch through which a current flows via a first terminal and a second terminal and which switches on or off in accordance with a voltage of a control terminal relative to a potential of the first terminal, the switch circuit comprising:
a voltage regulator that keeps a voltage between the first terminal and the second terminal of the semiconductor switch lower than or equal to a predetermined voltage; and
a diode having a cathode connected to the first terminal of the semiconductor switch.

5. The switch circuit according to claim 4, further comprising:
a second semiconductor switch through which a current flows via a third terminal and a fourth terminal and which switches on or off in accordance with a voltage of a second control terminal relative to a potential of the third terminal; and
a switching unit that simultaneously switches the semiconductor switch and the second semiconductor switch from on to off, wherein
the first terminal of the semiconductor switch is connected to the third terminal of the second semiconductor switch or the second terminal of the semiconductor switch is connected to the fourth terminal of the second semiconductor switch.

6. The switch circuit according to claim 1, wherein no current flows through the voltage regulator if a voltage applied to the voltage regulator is lower than the predetermined voltage and a current flows through the voltage regulator if the voltage applied to the voltage regulator equals the predetermined voltage.

7. A power source apparatus comprising:
the switch circuit according to claim 1; and
two capacitors that are connected to one another via the switch circuit.

8. The switch circuit according to claim 2, further comprising a second semiconductor switch through which a current flows via a third terminal and a fourth terminal and which switches on or off in accordance with a voltage of a second control terminal relative to a potential of the third terminal, wherein
the first terminal of the semiconductor switch is connected to the third terminal of the second semiconductor switch or the second terminal of the semiconductor switch is connected to the fourth terminal of the second semiconductor switch, and
the first switching unit simultaneously switches the semiconductor switch and the second semiconductor switch from on to off.

9. The switch circuit according to claim 2, wherein no current flows through the voltage regulator if a voltage applied to the voltage regulator is lower than the predetermined voltage and a current flows through the voltage regulator if the voltage applied to the voltage regulator equals the predetermined voltage.

10. The switch circuit according to claim 3, wherein no current flows through the voltage regulator if a voltage applied to the voltage regulator is lower than the predetermined voltage and a current flows through the voltage regulator if the voltage applied to the voltage regulator equals the predetermined voltage.

11. The switch circuit according to claim 4, wherein no current flows through the voltage regulator if a voltage applied to the voltage regulator is lower than the predetermined voltage and a current flows through the voltage regulator if the voltage applied to the voltage regulator equals the predetermined voltage.

12. The switch circuit according to claim 5, wherein no current flows through the voltage regulator if a voltage applied to the voltage regulator is lower than the predetermined voltage and a current flows through the voltage regulator if the voltage applied to the voltage regulator equals the predetermined voltage.
